(19) United States
(12) Patent Application Publication
(10) Pub. No.: US 2023/0032177 A1
(43) Pub. Date: Feb. 2, 2023

(54) ELECTRONIC DEVICES COMPRISING MULTILEVEL BITLINES, AND RELATED METHODS AND SYSTEMS

(71) Applicant: Micron Technology, Inc., Boise, ID (US)

(72) Inventors: Harsh Narendrakumar Jain, Boise, ID (US); Adam L. Olson, Boise, ID (US); Yoshiaki Fukuzumi, Yokohama (JP); Naveen Kaushik, Boise, ID (US); Richard J. Hill, Boise, ID (US); Lars P. Heineck, Boise, ID (US)

(21) Appl. No.: 17/443,521

(22) Filed: Jul. 27, 2021

(51) Int. Cl. H01L 27/11556; H01L 27/11582; G11C 5/02; H01L 23/00

(52) U.S. Cl. CPC H01L 27/11556; G11C 5/025; H01L 24/14; H01L 27/11582

(57) ABSTRACT

An electronic device comprising multilevel bitlines, pillar contacts, level 1 contacts, and level 2 contacts. The multilevel bitlines comprise first bitlines and second bitlines, with the first bitlines and second bitlines positioned at different levels. The pillar contacts are electrically connected to the first bitlines and to the second bitlines, the level 1 contacts are electrically connected to the first bitlines, and the level 2 contacts are electrically connected to the second bitlines. Each bitline of the first bitlines is electrically connected to a single pillar contact adjacent to the level 1 contacts and each bitline of the second bitlines is electrically connected to a single pillar contact adjacent to the level 2 contacts. Additional electronic devices are disclosed, as are methods of forming an electronic device and related systems.

### CROSS-REFERENCE TO RELATED APPLICATION

This application is related to U.S. Pat. Application Serial No. XX/XXX,XXX, entitled “ELECTRONIC DEVICES COMPRISING MULTILEVEL BITLINES AND RELATED METHODS AND SYSTEMS,” filed on even date herewith and assigned to the Assignee of the present application, the entire disclosure of which is hereby incorporated herein in its entirety by this reference.

### TECHNICAL FIELD

Embodiments disclosed herein relate to electronic devices and electronic device fabrication. More particularly, embodiments of the disclosure relate to electronic devices comprising multilevel bitlines and to related methods and systems.

### BACKGROUND

Electronic device (e.g., semiconductor device, memory device) designers often desire to increase the level of integration or density of features (e.g., components) within an electronic device by reducing the dimensions of the individual features and by reducing the separation distance between neighboring features. Electronic device designers also desire to design architectures that are not only compact, but offer performance advantages, as well as simplified designs. Reducing the dimensions and spacing of features has placed increasing demands on the methods used to form the electronic devices. One solution has been to form three-dimensional (3D) electronic devices, such as 3D NAND devices, in which memory cells are positioned vertically on a substrate. However, as the memory cells are formed at smaller dimensions and closer together, capacitance between adjacent bitlines increases. The increased bitline-bitline capacitance increases a time to program of the electronic device. An increase in bitline-bitline capacitance is also observed when a pitch of the bitlines is decreased. However, continuing to decrease the pitch of the bitlines is not possible as the dimensions and spacing of memory cells becoming smaller.

### BRIEF DESCRIPTION OF THE DRAWINGS

FIGS. 1A, 2A, 3A, 4A, 5A, 6A, 7A, 8A, and 9A are top down views illustrating the formation of a subblock of an electronic device including multilevel bitlines according to embodiments of the disclosure;

FIGS. 1B, 2B, 3B, 4B, 5B, 6B, 7B, 8B, and 9B are cross-sectional views, taken along the line A-A in FIGS. 1A, 2A, 3A, 4A, 5A, 6A, 7A, 8A, and 9A, respectively, illustrating the formation of a subblock of an electronic device including multilevel bitlines according to embodiments of the disclosure;

FIGS. 10A, 11A, 12A, 13A, 14A, 15A, 16A, 17A, and 18A are top down views illustrating the formation of a subblock of an electronic device including multilevel bitlines according to other embodiments of the disclosure;

FIGS. 10B, 11B, 12B, 13B, 14B, 15B, 16B, 17B, and 18B are cross-sectional views, taken along the line A-A in FIGS. 10A, 11A, 12A, 13A, 14A, 15A, 16A, 17A, and 18A, respectively, illustrating the formation of a subblock of an electronic device including multilevel bitlines according to other embodiments of the disclosure;

FIGS. 19A-19D are cross-sectional views, taken along the line B-B in FIG. 18A, that illustrate configurations of multilevel bitlines according to embodiments of the disclosure;

FIGS. 20A-27B are cross-sectional and top down views illustrating the formation of electronic devices including multilevel bitlines according to additional embodiments of the disclosure;

FIGS. 28A-29B are cross-sectional and top down views of electronic devices including multilevel bitlines according to additional embodiments of the disclosure;

FIG. 30 is a partial cutaway perspective view of a portion of an electronic device including the multilevel bitlines according to embodiments of the disclosure;

FIG. 31 is a functional block diagram of an electronic device including the electronic structures according to embodiments of the disclosure; and

FIG. 32 is a simplified block diagram of a system including the electronic structures according to embodiments of the disclosure.

### DETAILED DESCRIPTION

An electronic device (e.g., an apparatus, a semiconductor device, a memory device) that includes one or more multilevel bitlines is disclosed. The bitlines (e.g., data lines, digit lines) of the electronic device are located at multiple levels (elevations, heights) of the electronic device, with one set of bitlines extending continuously in a first level (L1) of the electronic device and another set of bitlines extending continuously in a second level (L2) of the electronic device. The set of bitlines in the first level is referred to herein as L1 bitlines or first bitlines, and the set of bitlines in the second level is referred to herein as L2 bitlines or second bitlines. The L1 bitlines and the L2 bitlines are not in physical contact with one another or in electrical contact with one another. The multilevel bitlines (e.g., a combination of the L1 bitlines and the L2 bitlines) are operably coupled to (e.g., electrically connected to) underlying contacts (e.g., pillar contacts), with each bitline of the multilevel bitlines electrically connected to a single (e.g., one) pillar contact. The multilevel bitlines and the pillar contacts are electrically connected to one another through L1 contacts and L2 contacts, with the L1 contacts and the L2 contacts exhibiting a different dimension (e.g., a length) from one another through materials of the electronic device. Each of the multilevel bitlines is electrically connected to a single (e.g., one) L1 contact or a single (e.g., one) L2 contact, which, in turn, is electrically connected to a single (e.g., one) pillar contact. The bitlines of the multilevel bitlines are also substantially equally spaced from one another. The electronic device containing the multilevel bitlines according to embodiments of the disclosure exhibits improved bitline-bitline capacitance in comparison to a conventional electronic device in which bitlines are located in only a single (e.g., one) level.

The following description provides specific details, such as material types, material thicknesses, and process conditions in order to provide a thorough description of embodiments described herein. However, a person of ordinary skill in the art will understand that the embodiments disclosed herein may be practiced without employing these specific details. Indeed, the embodiments may be practiced in conjunction with conventional fabrication techniques employed in the semiconductor industry. In addition, the description provided herein does not form a complete description of an electronic device or a complete process flow for manufacturing the electronic device and the structures described below do not form a complete electronic device. Only those process acts and structures necessary to understand the embodiments described herein are described in detail below. Additional acts to form a complete electronic device may be performed by conventional techniques.

Unless otherwise indicated, the materials described herein may be formed by conventional techniques including, but not limited to, spin coating, blanket coating, chemical vapor deposition (CVD), atomic layer deposition (ALD), plasma enhanced ALD, physical vapor deposition (PVD) (including sputtering, evaporation, ionized PVD, and/or plasma-enhanced CVD), or epitaxial growth. Alternatively, the materials may be grown in situ. Depending on the specific material to be formed, the technique for depositing or growing the material may be selected by a person of ordinary skill in the art. The removal of materials may be accomplished by any suitable technique including, but not limited to, etching (e.g., dry etching, wet etching, vapor etching), ion milling, abrasive planarization (e.g., chemical-mechanical planarization), or other known methods unless the context indicates otherwise.

Drawings presented herein are for illustrative purposes only, and are not meant to be actual views of any particular material, component, structure, electronic device, or electronic system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, the singular forms “a,” “an,” and “the” are intended to include the plural forms as well, unless the context clearly indicates otherwise.

As used herein, “and/or” includes any and all combinations of one or more of the associated listed items.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the term “conductive material” means and includes an electrically conductive material. The conductive material may include, but is not limited to, one or more of a doped polysilicon, undoped polysilicon, a metal, an alloy, a conductive metal oxide, a conductive metal nitride, a conductive metal silicide, and a conductively doped semiconductor material. By way of example only, the conductive material may be one or more of tungsten (W), tungsten nitride (WN_{y}), nickel (Ni), tantalum (Ta), tantalum nitride (TaN_{y}), tantalum silicide (TaSi_{X}), platinum (Pt), copper (Cu), silver (Ag), gold (Au), aluminum (Al), molybdenum (Mo), titanium (Ti), titanium nitride (TiN_{y}), titanium silicide (TiSiₓ), titanium silicon nitride (TiSi_{xNy}), titanium aluminum nitride (TiAlₓN_{y}), molybdenum nitride (MoNₓ), iridium (Ir), iridium oxide (IrO_{z}), ruthenium (Ru), ruthenium oxide (RuO_{z}), n-doped polysilicon, p-doped polysilicon, undoped polysilicon, and conductively doped silicon.

As used herein, the term “configured” refers to a size, shape, material composition, and arrangement of one or more of at least one structure and at least one apparatus facilitating operation of one or more of the structure and the apparatus in a pre-determined way.

As used herein, the phrase “coupled to” refers to structures operably connected with each other, such as electrically connected through a direct ohmic connection or through an indirect connection (e.g., via another structure).

As used herein, the term “dielectric material” means and includes an electrically insulative material. The dielectric material may include, but is not limited to, one or more of an insulative oxide material or an insulative nitride material. A dielectric oxide may be an oxide material, a metal oxide material, or a combination thereof. The dielectric oxide may include, but is not limited to, a silicon oxide (SiOₓ, silicon dioxide (SiO₂)), phosphosilicate glass, borosilicate glass, borophosphosilicate glass, fluorosilicate glass, aluminum oxide (AlO_{X}), gadolinium oxide (GdOₓ), hafnium oxide (HfOₓ), magnesium oxide (MgOₓ), niobium oxide (NbOₓ), tantalum oxide (TaOₓ), titanium oxide (TiOₓ), zirconium oxide (ZrO_{X}), hafnium silicate, a dielectric oxynitride material (e.g., SiOₓN_{y}), a dielectric carboxynitride material (e.g., SiOₓC_{z}N_{y}), a combination thereof, or a combination of one or more of the listed materials with silicon oxide. A dielectric nitride material may include, but is not limited to, silicon nitride.

As used herein, the term “electronic device” includes, without limitation, a memory device, as well as semiconductor devices which may or may not incorporate memory, such as a logic device, a processor device, or a radiofrequency (RF) device. Further, an electronic device may incorporate memory in addition to other functions such as, for example, a so-called "system on a chip" (SoC) including a processor and memory, or an electronic device including logic and memory. The electronic device may, for example, be a 3D electronic device, such as a 3D NAND Flash memory device.

As used herein, the term “etch stop” material means and includes a material that is resistant to removal (e.g., etch) relative to removal of one or more other exposed materials.

As used herein, the term “level” refers to a particular elevation (in a z direction) of a particular feature. Features that are present in different levels of the electronic device do not physically contact each other.

As used herein, the term “low-k dielectric material” means and includes a dielectric material, such as a dielectric oxide material, having a dielectric constant lower than the dielectric constant of a silicon oxide (SiOₓ, SiO₂) material or of a carbon-doped silicon oxide material that includes silicon atoms, carbon atoms, oxygen atoms, and hydrogen atoms. The dielectric constant of silicon dioxide is from about 3.7 to about 3.9. The term "low-k dielectric material" is a relative term and is distinguished from the term "dielectric material" by a relative value of its dielectric constant.

As used herein, the term “multilevel bitlines” refers to multiple bitlines (e.g. sets of bitlines) present at different locations (e.g., levels, elevations) in the electronic device. The bitlines include and are formed of a conductive material, with each set of the multilevel bitlines operably connected (e.g., electrically connected) to the pillar contacts and to access lines (e.g., wordlines) of the electronic device. The multilevel bitlines are electrically connected to the pillar contacts by contacts (e.g., L1 contacts, L2 contacts) adjacent to the different levels.

As used herein, reference to an element as being “on” or “over” another element means and includes the element being directly on top of, adjacent to (e.g., laterally adjacent to, vertically adjacent to), underneath, or in direct contact with the other element. It also includes the element being indirectly on top of, adjacent to (e.g., laterally adjacent to, vertically adjacent to), underneath, or near the other element, with other elements present therebetween. In contrast, when an element is referred to as being “directly on” or "directly adjacent to" another element, no intervening elements are present.

As used herein, the term “substantially” in reference to a given parameter, property, or condition means and includes to a degree that one of ordinary skill in the art would understand that the given parameter, property, or condition is met with a degree of variance, such as within acceptable manufacturing tolerances. By way of example, depending on the particular parameter, property, or condition that is substantially met, the parameter, property, or condition may be at least 90.0% met, at least 95.0% met, at least 99.0% met, or even at least 99.9% met.

As used herein, the term “substrate” means and includes a material (e.g., a base material) or construction upon which additional materials are formed. The substrate may be a an electronic substrate, a semiconductor substrate, a base semiconductor layer on a supporting structure, an electrode, an electronic substrate having one or more materials, layers, structures, or regions formed thereon, or a semiconductor substrate having one or more materials, layers, structures, or regions formed thereon. The materials on the electronic substrate or semiconductor substrate may include, but are not limited to, semiconductive materials, insulating materials, conductive materials, etc. The substrate may be a conventional silicon substrate or other bulk substrate comprising a layer of semiconductive material. As used herein, the term "bulk substrate" means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

As used herein, the terms “vertical,” “longitudinal,” “horizontal,” and “lateral” are in reference to a major plane of a structure and are not necessarily defined by Earth’s gravitational field. A “horizontal” or “lateral” direction is a direction that is substantially parallel to the major plane of the structure, while a "vertical" or "longitudinal" direction is a direction that is substantially perpendicular to the major plane of the structure. The major plane of the structure is defined by a surface of the structure having a relatively large area compared to other surfaces of the structure.

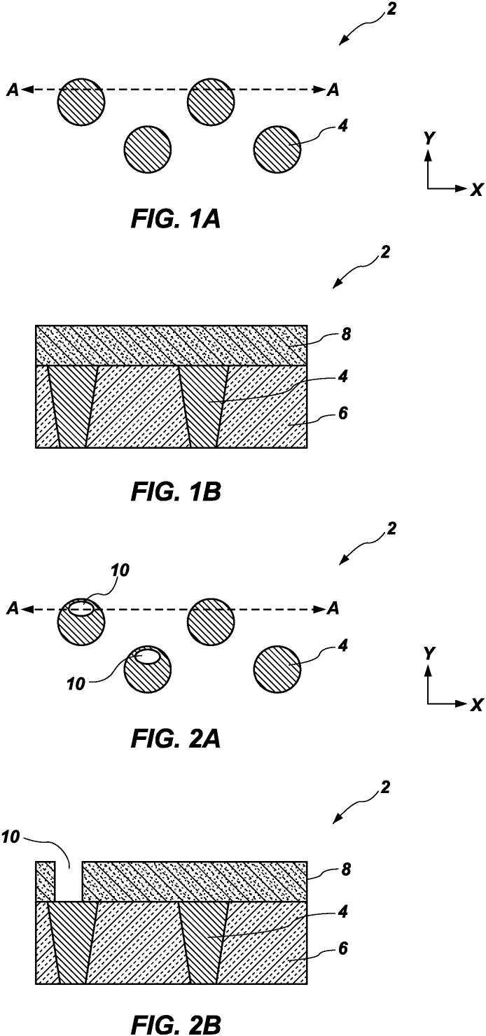

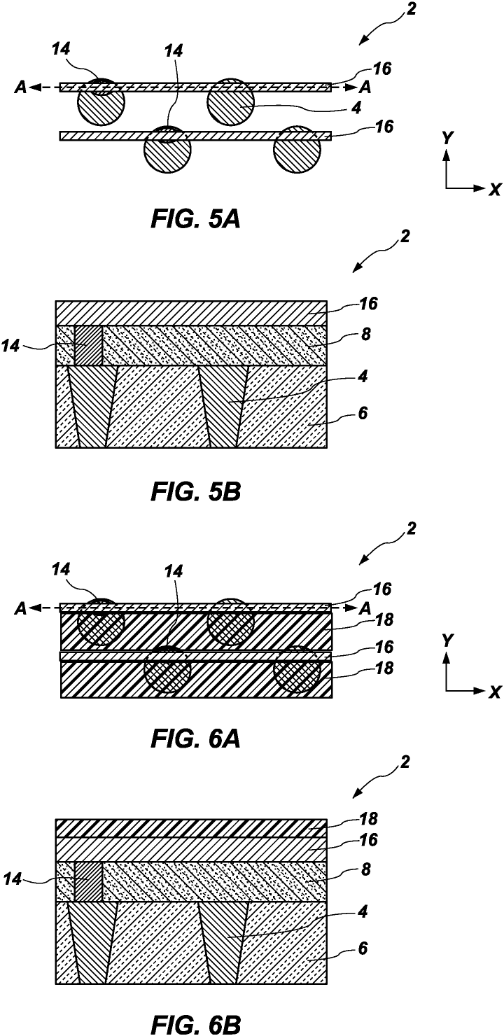

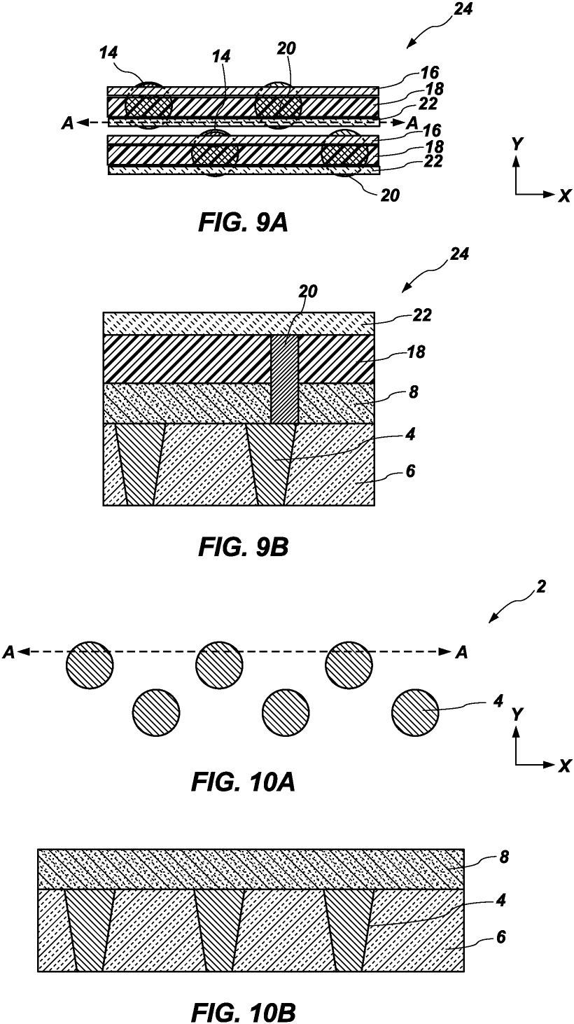

A method of forming an electronic device 24 (see FIGS. 9A and 9B) that includes multilevel bitlines 16, 22 (see FIGS. 5A, 5B, 9A, 9B, 14A, 14B, 18A, 18B) is shown in FIGS. 1A-9B. FIGS. 1A and 1B show a subblock 2 including pillar contacts 4, a first dielectric material 6, and a second dielectric material 8. Multiple subblocks 2 constitute a block (not shown) of the electronic device 24, with multiple blocks being present in the electronic device 24. The pillar contacts 4 may, for example, be configured to electrically connect to pillars (e.g. memory pillars, memory strings, channel strings) (not shown) adjacent to (e.g., below) the pillar contacts 4 and the first dielectric material 6. The pillar contacts 4 may be adjacent to (e.g., vertically adjacent to, on) and in direct electrical contact with contact plugs (not shown) of the pillars, electrically connecting the pillars to the pillar contacts 4. The pillars are present in tiers (not shown) of alternating dielectric materials and conductive materials on the substrate. The pillars may, for example, be memory pillars and include a channel material of a cell film surrounding a fill material. The cell film may include a cell material and the channel material is formed adjacent to (e.g., around) the cell material. The cell material and the channel material in the tiers define memory cells of the electronic device 24. Alternatively, one or more of the pillars in the electronic device 24 may be dummy pillars.

As shown in FIGS. 1A and 1B, the subblock 2 includes four pillar contacts 4 within the first dielectric material 6, and the second dielectric material 8 is adjacent to (e.g., over) the pillar contacts 4 and the first dielectric material 6. For simplicity, the first dielectric material 6 is not shown in the top down view of FIG. 1A. The pillar contacts 4 and the first dielectric material 6 are adjacent (e.g., on, over) a substrate (not shown). The pillar contacts 4 are configured in rows (e.g., two rows) in the subblock 2, with adjacent pillar contacts 4 substantially equally spaced from one another in a horizontal direction. The pillar contacts 4 in a first row may be equally spaced from the pillar contacts 4 in a second row. The pillar contacts 4 are also substantially equally spaced from one another in a vertical direction. The pillar contacts 4 may be configured in a staggered (e.g., alternating) configuration, as shown in FIG. 1A.

Each of the first dielectric material 6 and the second dielectric material 8 of the subblock 2 may be formed from an electrically insulative material, such as an electrically insulative oxide material. Each of the materials of the first dielectric material 6 and the second dielectric material 8 may exhibit the same chemical composition or a different chemical composition. Even if the first dielectric material 6 and the second dielectric material 8 are formed from the same chemical composition, the first dielectric material 6 and the second dielectric material 8 may be visually distinguishable if the first dielectric material 6 and the second dielectric material 8 are formed at different times (e.g., by different process acts). In some embodiments, each of the first dielectric material 6 and the second dielectric material are formed of and include silicon dioxide.

The pillar contacts 4 are formed in the first dielectric material 6 by conventional techniques, such as by conventional photolithography techniques. The pillar contacts 4 may be formed of and include at least one conductive material (e.g., an electrically conductive material). In some embodiments, the pillar contacts 4 are formed of and include tungsten. By way of example only, openings (not shown) are formed in the first dielectric material 6 and the conductive material of the pillar contacts 4 is formed in the openings. As shown in FIG. 1B, the second dielectric material 8 is adjacent to (e.g., on, over) the pillar contacts 4 and first dielectric material 6. The second dielectric material 8 may be formed by conventional techniques. For simplicity, the second dielectric material 8 is not shown in the top down view of FIG. 1A. The second dielectric material 8 may be formed at a thickness sufficient to provide desired dimensions of subsequently-formed level 1 (L1) contacts 14 (see FIGS. 4A and 4B) between first bitlines 16 (see FIGS. 5A and 5B) and the pillar contacts 4.

Openings 10 are formed in the second dielectric material 8, as shown in FIGS. 2A and 2B, exposing a portion of the underlying pillar contacts 4. For simplicity, the second dielectric material 8 is not shown in the top down view of FIG. 2A. The openings 10 may be formed by conventional techniques. The openings 10 are formed adjacent to (e.g., over) only some of the pillar contacts 4, while no openings 10 are formed adjacent to other pillar contacts 4. For example, and as illustrated in FIGS. 2A and 2B, the openings 10 may be formed over two pillar contacts 4 (e.g., over pillar contacts 4 on the left side of the subblock 2), while no openings 10 are formed over the two other pillar contacts 4 (e.g., over pillar contacts 4 on the right side of the subblock 2). The openings 10 correspond to locations where the L1 contacts 14 (see FIGS. 4A and 4B) are ultimately to be formed. By forming the openings 10 adjacent to (e.g., over) only some of the pillar contacts 4, these pillar contacts 4 may be electrically connected to the first bitlines 16 (see FIGS. 5A and 5B) while the other pillar contacts 4 may be electrically connected to the second bitlines 22 (see FIGS. 9A and 9B) following subsequently-conducted process acts.

The openings 10 may be adjacent to (e.g., over) the pillar contacts 4, exposing a desired portion of the pillar contacts 4, and may extend through the second dielectric material 8. In FIG. 2A, the openings 10 are shown as being adjacent to (e.g., over) a top portion of the pillar contacts 4, exposing a lateral portion of the left side of the pillar contacts 4 in FIG. 2B. As shown in FIG. 2B, the opening 10 is laterally offset from a central portion of the pillar contacts 4. Alternatively, the openings 10 may be located adjacent to (e.g., over) a bottom portion of the pillar contacts 4, in which case a lateral portion of the right side of the pillar contacts 4 in FIG. 2B is exposed. Dimensions of the openings 10 may be selected to expose a desired surface area of the pillar contacts 4.

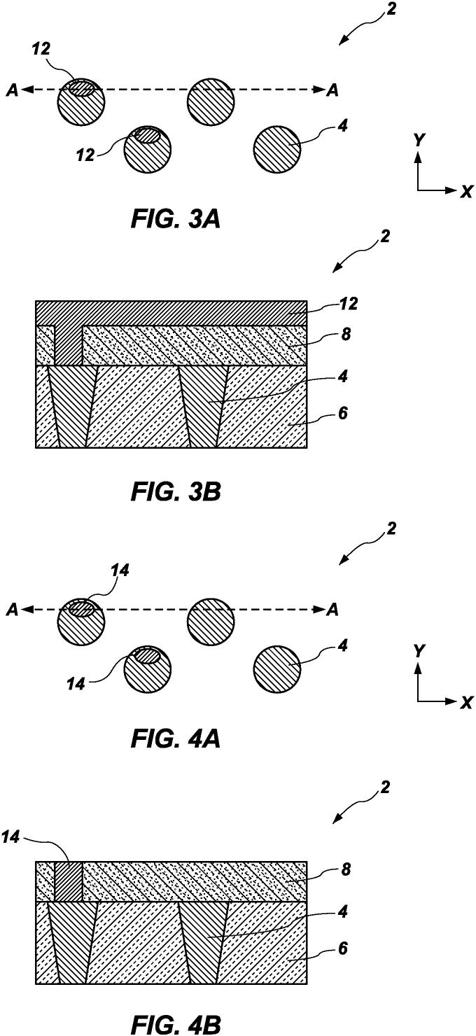

As shown in FIGS. 3A and 3B, a conductive material 12 is formed in the openings 10. While a damascene process is shown, a subtractive process may also be used to form the conductive material 12. In some embodiments, the conductive material 12 is n-doped polysilicon, p-doped polysilicon, or undoped polysilicon. In other embodiments, the conductive material 12 is tungsten. However, another conductive metal may be used, such as copper, molybdenum, or ruthenium. The conductive material 12 may be the same as or different than the conductive material of the pillar contacts 4. The conductive material 12 may be formed in the openings 10 by conventional techniques and may substantially fill (e.g., substantially completely fill) the openings 10. For simplicity, the second dielectric material 8 is not shown in the top down view of FIG. 3A. In FIG. 3A, the conductive material 12 in the openings 10 is adjacent to (e.g., over) the top portion of the pillar contacts 4. Therefore, the conductive material 12 directly contacts the lateral portion of the left side of the pillar contacts 4, as shown in FIG. 3B. However, if the conductive material 12 in the openings 10 is adjacent to (e.g., over) the bottom portion of the pillar contacts 4, the conductive material 12 may directly contact the lateral portion of the right side of the pillar contacts 4.

The conductive material 12 may also be formed adjacent to (e.g., over) the second dielectric material 8, as shown in FIG. 3B. Excess conductive material 12 may be removed, as shown in FIGS. 4A and 4B, forming the L1 contacts 14 adjacent to (e.g., over) the pillar contacts 4. For simplicity, the second dielectric material 8 is not shown in the top down view of FIG. 4A. A portion of the conductive material 12 over the second dielectric material 8 may be removed, such as by an abrasive planarization (e.g., chemical-mechanical planarization (CMP)) process, with the second dielectric material 8 functioning as an etch stop during the removal of the conductive material 12. As shown in FIG. 4A, the L1 contacts 14 are located adjacent to (e.g., over) the top portion of the pillar contacts 4, and directly contact the lateral portion of the left side of the pillar contacts 4 in FIG. 4B. Alternatively, the L1 contacts 14 may be adjacent to (e.g., over) the bottom portion of the pillar contacts 4, and directly contact the lateral portion of the right side of the pillar contacts 4 in FIG. 4B. By forming the L1 contacts 14 adjacent to (e.g., over) only some of the pillar contacts 4, these pillar contacts 4 are electrically connected to the first bitlines 16 (see FIGS. 5A and 5B) through the L1 contacts 14, while the remaining pillar contacts 4 are electrically connected to the second bitlines 22 (see FIGS. 9A and 9B) through the L2 contacts 20 following subsequently-conducted process acts.

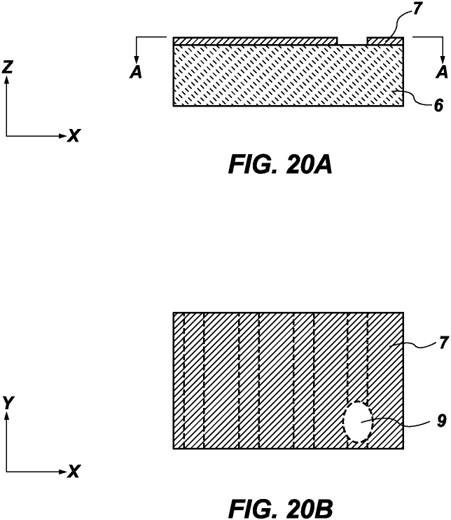

The first bitlines 16 are formed adjacent to (e.g., over) the L1 contacts 14 and the second dielectric material 8, as shown in FIGS. 5A and 5B. For simplicity, the second dielectric material 8 is not shown in the top down view of FIG. 5A. The first bitlines 16 are formed from and include a conductive material. The conductive material may be the same as or different than the conductive material of the pillar contacts 4 or the conductive material of the L1 contacts 14. The first bitlines 16 are present at a single level, L1, and are also referred to herein as the L1 bitlines. The first bitlines 16 are continuous (e.g., extend substantially continuously) in the horizontal direction of FIG. 5A. Each of the L1 contacts 14 may be configured to be in electrical contact (e.g., electrical connection) with alternate (e.g., every other) first bitlines 16. A portion of each of the first bitlines 16 directly contacts the L1 contacts 14, electrically connecting the first bitlines 16 to the pillar contacts 4. Therefore, each L1 contact 14 is electrically connected to one (e.g., a single) first bitline 16 in the subblock 2. The first bitlines 16 are also electrically connected to wordlines 2006 (see FIGS. 20). Each of the first bitlines 16 may be formed at substantially the same pitch and exhibit substantially the same critical dimension (CD) as one another. The pitch of the first bitlines 16 may range from about 50 nm to about 75 nm, such as from about 55 nm to about 70 nm, from about 55 nm to about 75 nm, from about 60 nm to about 75 nm, from about 65 nm to about 75 nm, or from about 70 nm to about 75 nm. As shown most clearly in FIG. 5A, the first bitlines 16 are equally spaced from one another in the vertical direction, and spaces between the vertically adjacent first bitlines 16 exhibit substantially the same dimensions as one another. However, the CD of the first bitlines 16 may be different than the CD of the spaces between the first bitlines 16.

The first bitlines 16 may be formed by conventional techniques, such as by using a spacer process, followed by a pitch multiplication (e.g., pitch doubling, pitch quadrupling) process, and a trim process. A width (e.g., the CD) of the first bitlines 16 may be selected depending on desired electrical performance characteristics of the electronic device 24 containing the first bitlines 16. As shown in FIG. 5A, the CD of the first bitlines 16 may substantially correspond to (e.g., be substantially the same as) a width of the L1 contacts 14. However, the width of the first bitlines 16 may be greater than (e.g., slightly greater than) or less than (e.g., slightly less than) the width of the L1 contacts 14, depending on the desired electrical performance characteristics of the electronic device 24 containing the first bitlines 16. The width of the first bitlines 16 may range from about 5 nm to about 15 nm, such as from about 5 nm to about 10 nm, from about 10 nm to about 15 nm, from about 8 nm to about 12 nm, or from about 10 nm to about 12 nm. The first bitlines 16 may be subjected to an abrasive planarization process, such as a CMP process, to reduce surface roughness of the first bitlines 16.

As shown in FIGS. 6A and 6B, a low-k dielectric material 18 is formed adjacent to (e.g., over) the first bitlines 16. The low-k dielectric material 18 may, for example, be an organic material, an inorganic material, or a dielectric material containing a dopant. In some embodiments, the low-k dielectric material 18 is an interlayer dielectric (ILD) material. The low-k dielectric material 18 may be formed in the spaces between adjacent first bitlines 16, such as substantially completely filling the spaces between the adjacent first bitlines 16 without forming gaps (e.g., voids) or so-called "breadloafing" in the low-k dielectric material 18. Excess low-k dielectric material 18 may be removed from over the first bitlines 16, such as by a CMP process, with the first bitlines 16 functioning as an etch stop during the CMP process. Depending on desired capacitance requirements for the electronic device 24, additional low-k dielectric material 18 may subsequently be formed on the first bitlines 16, increasing the thickness of the low-k dielectric material 18 relative to the thickness as initially formed. Alternatively, the spaces between adjacent first bitlines 16 may include an air gap (e.g., a void) rather than the low-k dielectric material 18. The air gap may be empty of a solid material and/or liquid material. However, the air gap may contain a gaseous material (e.g., air, oxygen, nitrogen, argon, helium, or a combination thereof).

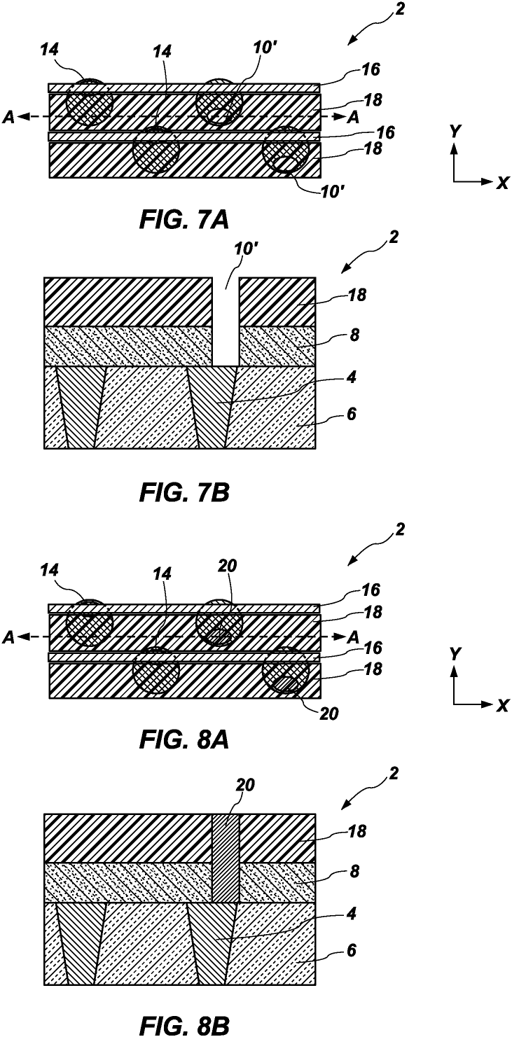

As shown in FIGS. 7A and 7B, openings 10' are formed and expose other (e.g., the remaining) pillar contacts 4 in the first dielectric material 6. As shown in FIG. 7A, the openings 10' are formed adjacent to (e.g., over) the pillar contacts 4 on the right side of the subblock 2. By way of example only, the openings 10' may be formed adjacent to only the pillar contacts 4 on the right side of the subblock 2, as shown most clearly in the cross-section of FIG. 7B. By forming the openings 10' adjacent to (e.g., over) only these pillar contacts 4, the pillar contacts 4 on the right side of the subblock 2 may be electrically connected to the second bitlines 22 (see FIGS. 9A and 9B) while the pillar contacts 4 on the left side of the subblock 2 may be electrically connected to the first bitlines 16 (see FIGS. 6A and 6B). The openings 10' may be formed by conventional techniques, such as by conducting one or more etch processes. A single etch process may be conducted to form the openings 10' or multiple etch processes may be conducted to remove each of the low-k dielectric material 18 and the second dielectric material 8. The openings 10' extend through the low-k dielectric material 18 and the second dielectric material 8 to expose the pillar contacts 4 that were not exposed by previously-conducted process acts, such as by the process acts shown in FIGS. 2A and 2B. The locations of the openings 10' correspond to locations where level 2 (L2) contacts 20 (see FIGS. 8A and 8B) are ultimately to be formed. Dimensions of the openings 10' may be selected to enable electrical connection of the pillar contacts 4 to the second bitlines 22. In FIGS. 7A and 7B, the openings 10' are shown as being adjacent to (e.g., over) the bottom portion of the pillar contacts 4, exposing the lateral portion of the right side of the pillar contacts 4. However, the relative positions of the openings 10, 10' may be switched so that the openings 10' are located at the top portion of the pillar contacts 4 and the openings 10 are located at the bottom portion of the pillar contacts 4.

As shown in FIGS. 8A and 8B, a conductive material is formed in the openings 10' to form the L2 contacts 20 that extend through the low-k dielectric material 18 and the second dielectric material 8. The conductive material of the L2 contacts 20 may be the same as or different than the conductive material of the first bitlines 16, the conductive material of the L1 contacts 14, or the conductive material of the pillar contacts 4. As shown by a comparison of FIGS. 6B and 8B, the L2 contacts 20 exhibit a greater length than a length of the L1 contacts 14 since the L2 contacts 20 extend through the low-k dielectric material 18 and the second dielectric material 8.

As shown in FIGS. 9A and 9B, a conductive material is formed over the L2 contacts 20 and the low-k dielectric material 18, forming the second bitlines 22. The second bitlines 22 are present at a single level, L2. The second bitlines 22 are electrically connected to the L2 contacts 20 and to wordlines 2006 (see FIGS. 20). The second bitlines 22 are present at a different level, L2, and may also be referred to herein as the L2 bitlines. The conductive material may be the same as or different than the conductive material of the pillar contacts 4, the conductive material of the L1 contacts 14, the conductive material of the first bitlines 16, or the conductive material of the L2 contacts 20. The second bitlines 22 may be formed by conventional techniques. A portion of each of the second bitlines 22 may directly contact the L2 contacts 20, electrically connecting the second bitlines 22 to the pillar contacts 4. Each L2 contact 20 is electrically connected to one (e.g., a single) second bitline 22 in the subblock 2. The second bitlines 22 are continuous in the horizontal direction of FIG. 9A. The second bitlines 22 are also electrically connected to wordlines 2006 (see FIGS. 20). Each of the second bitlines 22 may be formed at substantially the same pitch and exhibit substantially the same CD, with the pitch and CD within the ranges disclosed above for the first bitlines 16. As shown most clearly in FIG. 9A, the second bitlines 22 are equally spaced from one another in the vertical direction, and spaces between the second bitlines 22 exhibit substantially the same dimensions as one another. However, the CD of the second bitlines 22 may be different than the CD of the spaces between the second bitlines 22. As also shown in FIG. 9A, a width of the second bitlines 22 may substantially correspond to a width of the L2 contacts 20. However, the width of the second bitlines 22 may be greater than (e.g., slightly greater than) or less than (e.g., slightly less than) the width of the L2 contacts 20, depending on the desired electrical performance characteristics of the electronic device 24 containing the first bitlines 16 and the second bitlines 22.

The multilevel bitlines include the first bitlines 16 and the second bitlines 22, each of which are continuous materials that extend in the horizontal direction of FIG. 9A. The first bitlines 16 and the second bitlines 22 are equally spaced from one another and run parallel to one another in the horizontal direction of FIG. 9A. Each of the pillar contacts 4 may be electrically connected to the first bitline 16 or to the second bitline 22 by one of the L1 contacts 14 or one of the L2 contacts. Each of the first bitlines 16 and the second bitlines 22 is electrically connected to the pillar contacts 4 by a separate contact (i.e., a single L1 contact 14, a single L2 contact 20). While two levels of bitlines are described and illustrated, two or more levels of bitlines may be present in the electronic device 24.

While FIGS. 1A-9B illustrate four pillar contacts 4 and four bitlines 16, 22 (e.g., the multilevel bitlines), more than four pillar contacts 4 and more than four bitlines 16, 22 may be present. By way of example only, five contacts, six contacts, or more may be present in the subblock 2, with a corresponding number of bitlines present, such as five bitlines, six bitlines, or more. As shown, for example, in FIGS. 10A and 10B, six pillar contacts 4 may be present, with the pillar contacts 4 configured in two rows in the subblock 2, with laterally adjacent pillar contacts 4 substantially equally spaced from one another. The pillar contacts 4 are configured in a staggered (e.g., alternating) configuration. The pillar contacts 4 are also equally spaced from one another in the vertical direction of FIG. 10A. A method of forming the six pillar contacts 4, six corresponding L1 contacts 14, six corresponding L2 contacts 20, and six multilevel bitlines 16, 22 is shown in FIGS. 10A-19.

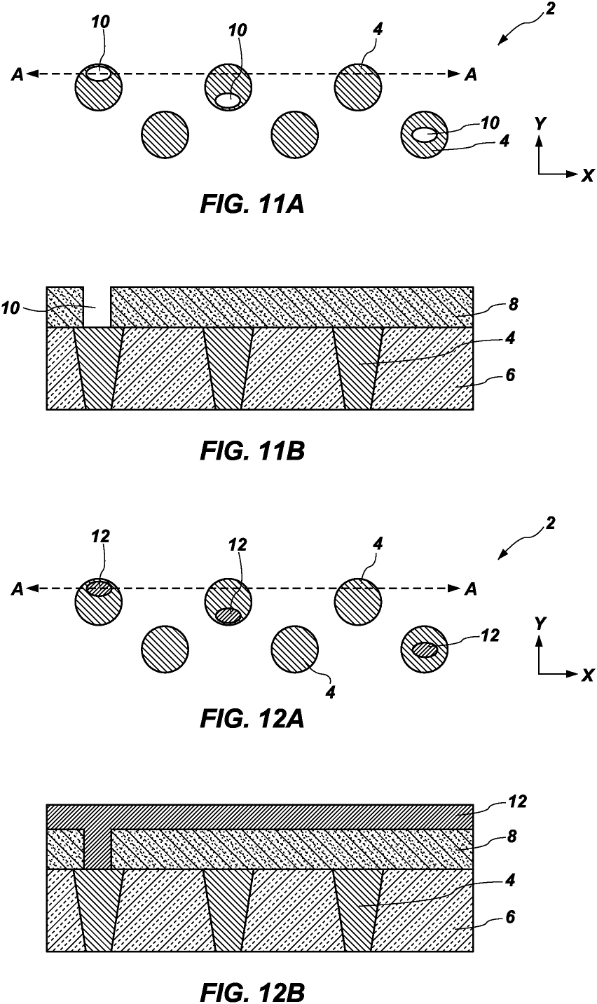

The pillar contacts 4, first dielectric material 6, and second dielectric material 8 may be formed as described above for FIGS. 1A and 1B. Openings 10, such as three openings 10, may be formed through the second dielectric material 8 to expose some of the pillar contacts 4, as shown in FIGS. 11A and 11B. The openings 10 may be formed as described above for FIGS. 2A and 2B. The openings 10 may be formed adjacent to (e.g., over) a lateral portion of the pillar contacts 4 or adjacent to (e.g., over) a central portion of the pillar contacts 4. By way of example only, two openings 10 may be adjacent to the lateral portions of the pillar contacts 4 and the third opening 10 may be adjacent to the central portion of the pillar contacts 4, as shown most clearly in FIG. 11A. While FIGS. 11A and 11B show the openings 10 as being adjacent to (e.g., over) the first, third, and sixth pillar contacts 4 (from left to right in FIG. 11A), other configurations of the openings 10 are possible. The openings 10 may, for example, be adjacent to (e.g., over) other combinations of three pillar contacts 4, such as the first, third, and fourth pillar contacts 4 (from left to right in FIG. 11A), the first, second, and third pillar contacts 4 (from left to right in FIG. 11A), the first, second, and fourth pillar contacts 4 (from left to right in FIG. 11A), the first, second, and fifth pillar contacts 4 (from left to right in FIG. 11A), the first, second, and sixth pillar contacts 4 (from left to right in FIG. 11A), the second, third, and fourth pillar contacts 4 (from left to right in FIG. 11A), the second, third, and fifth pillar contacts 4 (from left to right in FIG. 11A), the second, third, and sixth pillar contacts 4 (from left to right in FIG. 11A), the second, fifth, and sixth pillar contacts 4 (from left to right in FIG. 11A), the third, fourth, and fifth pillar contacts 4 (from left to right in FIG. 11A), the third, fourth, and sixth pillar contacts 4 (from left to right in FIG. 11A), or the fourth, fifth, and sixth pillar contacts 4 (from left to right in FIG. 11A).

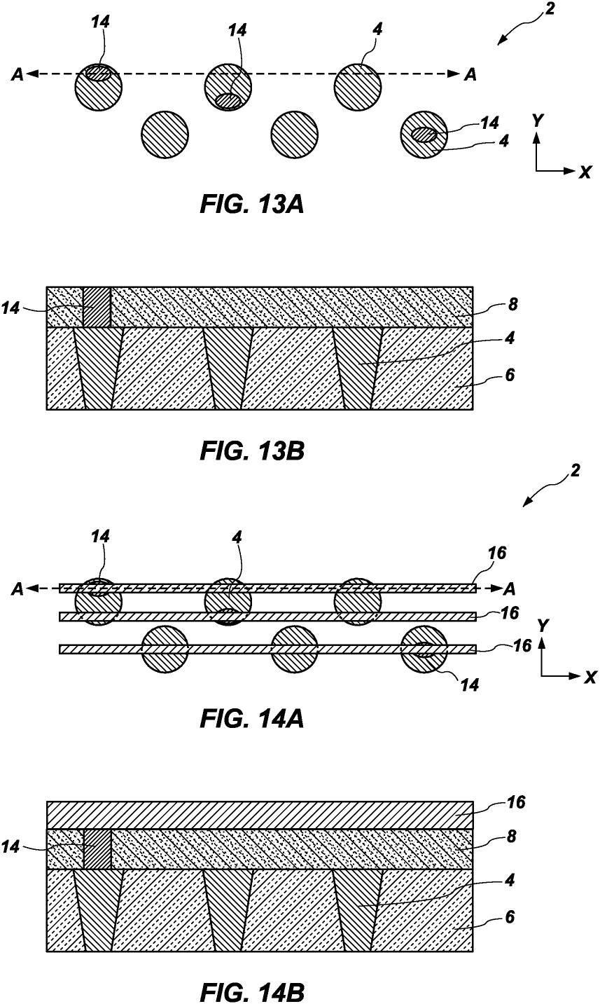

As shown in FIGS. 12A-13B, a conductive material 12 is formed in the openings 10 and a portion of the conductive material 12 is removed to form the L1 contacts 14. The conductive material 12 may be formed and removed as described above for FIGS. 3A-4B. The conductive material 12 may be the same as or different than the conductive material of the pillar contacts 4. Two L1 contacts 14 may be adjacent to the lateral portions of the pillar contacts 4 and one L1 contact 14 may be adjacent to the central portion of the pillar contacts 4.

First bitlines 16 are formed adjacent to (e.g., over) the L1 contacts 14 and the second dielectric material 8, as shown in FIGS. 14A and 14B. Portions of each of the first bitlines 16 may directly contact the L1 contacts 14, electrically connecting the first bitlines 16 to the pillar contacts 4. Each of the first bitlines 16 is electrically connected to a separate L1 contact 14. The first bitlines 16 are also electrically connected to wordlines 2006 (see FIGS. 20) by the pillar contacts 4. As shown most clearly in FIG. 14A, the first bitlines 16 are equally spaced from one another in the vertical direction. The first bitlines 16 may be formed as described above for FIGS. 5A and 5B, except that three first bitlines 16 are present and located over the L1 contacts 14. The conductive material of the first bitlines 16 may be the same as or different than the conductive material of the pillar contacts 4 or the conductive material of the L1 contacts 14. The first bitlines 16 are present at a single level, L1. A width of the first bitlines 16 may be substantially the same as, slightly greater than, or slightly less than the width of the L1 contacts 14, depending on desired electrical performance characteristics of the electronic device 24' containing the first bitlines 16.

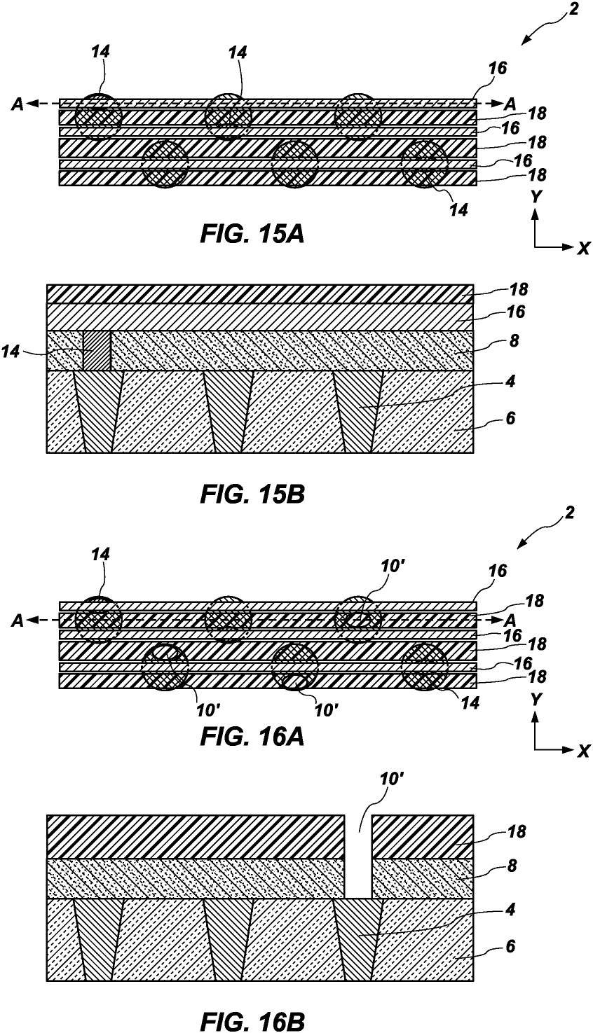

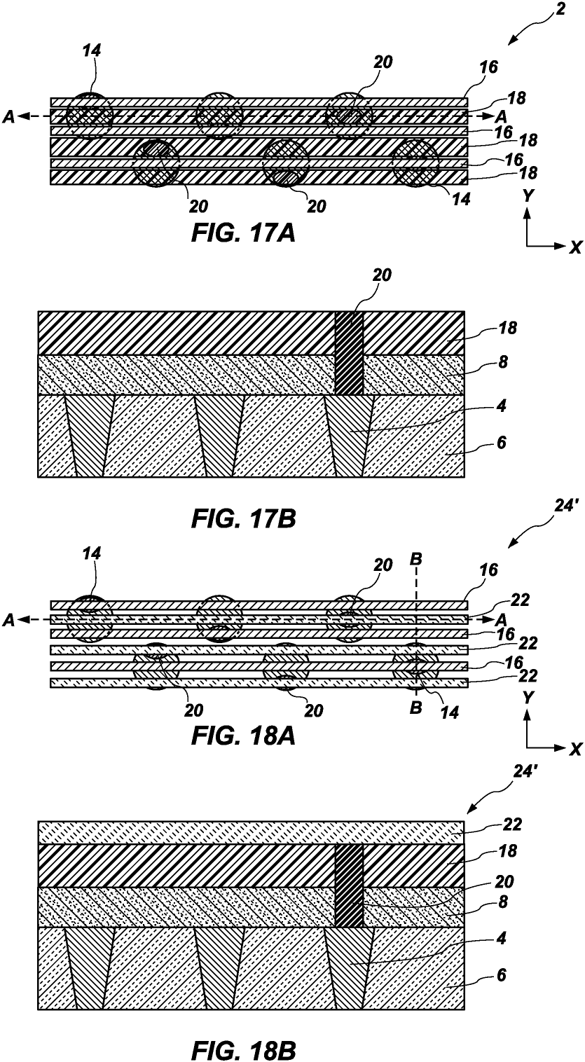

A low-k dielectric material 18 is formed adjacent to (e.g., over) the first bitlines 16, as shown in FIGS. 15A and 15B. The low-k dielectric material 18 may be formed as described above for FIGS. 6A and 6B. Openings 10' are formed in the low-k dielectric material 18 and the second dielectric material 8, exposing the remaining pillar contacts 4, as shown in FIGS. 16A and 16B. The openings 10' correspond to a location at which L2 contacts 20 (see FIGS. 17A and 17B) are ultimately to be formed. The openings 10' may be formed as described above for FIGS. 7A and 7B. As shown in FIG. 16A, two openings 10' may be formed adjacent to the lateral portions of the pillar contacts 4 and the third opening 10' may be formed adjacent to the central portion of the pillar contacts 4. By forming the openings 10' adjacent to (e.g., over) only some of the pillar contacts 4, these pillar contacts 4 may be electrically connected to second bitlines 22 (see FIGS. 18A and 18B) while the other pillar contacts 4 are electrically connected to the first bitlines 16 (see FIGS. 14A and 14B).

As shown in FIGS. 17A and 17B, a conductive material is formed in the openings 10' to form the L2 contacts 20 that extend through the low-k dielectric material 18 and the second dielectric material 8. The conductive material of the L2 contacts 20 may be the same as or different than the conductive material of the pillar contacts 4, the conductive material of the L1 contacts 14, or the conductive material of the first bitlines 16. The L2 contacts 20 may be formed as described above for FIGS. 8A and 8B. The L2 contacts 20 are electrically connected to the second bitlines 22 and to the pillar contacts 4.

As shown in FIGS. 18A and 18B, a conductive material is formed over the L2 contacts 20 and the low-k dielectric material 18, forming the second bitlines 22 of electronic device 24'. The second bitlines 22 are present at a single level, L2. For simplicity, the low-k dielectric material 18 is not shown in FIG. 18A. The second bitlines 22 may be formed as described above for FIGS. 9A and 9B. The conductive material of the second bitlines 22 may be the same as or different than the conductive material of the pillar contacts 4, the conductive material of the L1 contacts 14, the conductive material of the first bitlines 16, or the conductive material of the L2 contacts 20. Portions of each of the second bitlines 22 may directly contact the L2 contacts 20, electrically connecting the second bitlines 22 to the pillar contacts 4. The second bitlines 22 are present at a different level, L2, than the level of the first bitlines 16. The second bitlines 22 are also electrically connected to wordlines 2006 (see FIGS. 20) by the pillar contacts 4. The second bitlines 22 are equally spaced from one another, as shown most clearly in FIG. 18A. As also shown in FIG. 18A, a width of the second bitlines 22 may be substantially the same as, slightly greater than, or slightly less than the width of the L2 contacts 20, depending on desired electrical performance characteristics of the electronic device 24' containing the multilevel bitlines 16, 22. The multilevel bitlines include the first bitlines 16 and the second bitlines 22, each of which are continuous materials that extend in the horizontal direction of FIG. 18A. The first bitlines 16 and the second bitlines 22 are equally spaced from one another and run parallel to one another in the horizontal direction of FIG. 18A. Each of the pillar contacts 4 may be electrically connected to the first bitline 16 or to the second bitline 22 by one of the L1 contacts 14 or one of the L2 contacts. Each of the first bitlines 16 and the second bitlines 22 is electrically connected to the pillar contacts 4 by a separate contact (i.e., a single L1 contact 14, a single L2 contact 20). While two levels of bitlines are described and illustrated, two or more levels of bitlines may be present in the electronic device 24'.

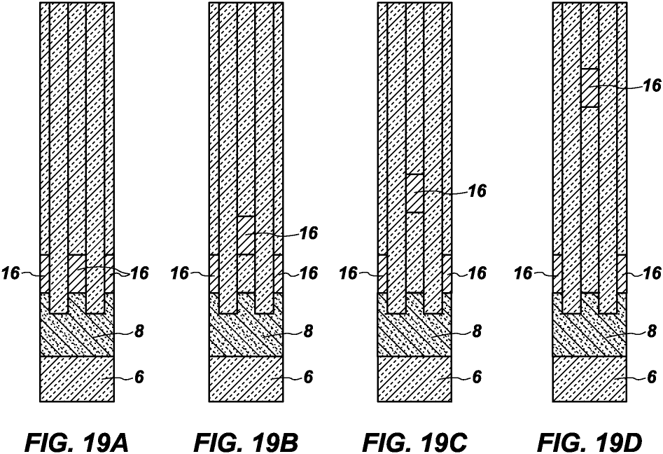

A cross-section of the electronic device 24' along line B-B of FIG. 18A is shown in FIGS. 19A-19D, with three first bitlines 16 adjacent to one another in the horizontal direction. FIGS. 19A-19D illustrate possible locations for the first bitlines 16 relative to on another. FIG. 19A shows the first bitlines 16 positioned laterally adjacent to one another and separated from one another by one or more dielectric materials. However, one or more of the first bitlines 16 may be offset in the vertical direction from the other first bitlines 16, as shown in FIGS. 19B-19D. In each of FIGS. 19B-19D, one of the first bitlines 16 is offset in the vertical direction from the two other first bitlines 16. However, the offset first bitline 16 may be present at any location in the vertical direction, not just the indicated location, from the two other first bitlines 16. Forming the first bitlines 16 to be offset from one another may be conducted by conventional techniques. One or more of the second bitlines 22 may also be offset from one another. Similarly, the multilevel bitlines 16, 22 in the electronic device 24 may be offset from one another.

As shown in FIGS. 9A, 9B, 18A, and 18B, the multilevel bitlines 16, 22 of the electronic devices 24, 24' are electrically connected to the pillar contacts 4 by the L1 contacts 14 and the L2 contacts 20, respectively. Each bitline of the L1 bitlines 16 is electrically connected to a single pillar contact 4 by a single L1 contact 14 and each bitline of the L2 bitlines 22 is electrically connected to a single pillar contact 4 by a single L2 contact 20. During use and operation of the electronic device 24, 24' containing the first bitlines 16 and the second bitlines 22, each of the first bitlines 16 and the second bitlines 22 may be separately controlled by a respective select gate drain (SGD) 2008 (see FIGS. 20) of the subblock 2. The select gate drains 2008 are formed adjacent to (e.g., over) the first bitlines 16 and the second bitlines 22, as known in the art. The ability to separately control the SGDs 2008 enables the first bitlines 16 and the second bitlines 22 to be separately controlled. The multilevel bitlines 16, 22 of the electronic devices 24, 24' may be formed at smaller pitches than bitlines of conventional electronic devices. Therefore, the multilevel bitlines 16, 22 according to embodiments of the disclosure may achieve reduced bitline-bitline capacitance even while the first and second bitlines 16, 22 are formed at lower pitches. Additionally, the bitline-bitline capacitance may be reduced by forming the first bitlines 16 and the second bitlines 22 in a staggered configuration. The multilevel bitlines 16, 22 according to embodiments of the disclosure provide improved bitline-bitline capacitance between adjacent first and second bitlines 16, 22 since the bitlines are in the staggered configuration. The improved bitline-bitline capacitance may be achieved even as the pitch of the first and second bitlines 16, 22 is reduced. In other words, for a given pitch of the first and second bitlines 16, 22, the bitline-bitline capacitance is reduced compared to the bitline-bitline capacitance of a conventional electronic device. The staggered configuration of the bitlines also enables further scaling of the electronic device in the x- and y-directions.

Accordingly, an electronic device is disclosed and comprises multilevel bitlines, pillar contacts, level 1 contacts, and level 2 contacts. The multilevel bitlines comprise first bitlines and second bitlines, with the first bitlines and second bitlines positioned at different levels. The pillar contacts are electrically connected to the first bitlines and to the second bitlines, the level 1 contacts are electrically connected to the first bitlines, and the level 2 contacts are electrically connected to the second bitlines. Each bitline of the first bitlines is electrically connected to a single pillar contact adjacent to the level 1 contacts and each bitline of the second bitlines is electrically connected to a single pillar contact adjacent to the level 2 contacts.

Accordingly, another electronic device is disclosed and comprises multilevel bitlines comprising first bitlines and second bitlines. The first bitlines and the second bitlines are parallel to one another and equally spaced from one another. Level 1 contacts are adjacent to the first bitlines, with each of the first bitlines electrically connected to a single level 1 contact. Level 2 contacts are adjacent to the second bitlines, with each of the second bitlines electrically connected to a single level 2 contact. Each bitline of the first bitlines is electrically connected to a single pillar contact adjacent to the level 1 contact and each bitline of the second bitlines is electrically connected to a single pillar contact adjacent to the level 2 contact.

Accordingly, a method of forming an electronic device is disclosed and comprises forming pillar contacts in a first dielectric material, forming a second dielectric material adjacent to the pillar contacts, and forming openings through the second dielectric material to expose the pillar contacts. A conductive material is formed in the openings to form level 1 contacts. Level 1 bitlines are formed in electrical contact with the level 1 contacts. A low-k dielectric material is formed over the level 1 bitlines. Additional openings are formed through the low-k dielectric material and the second dielectric material to expose additional pillar contacts. A conductive material is formed in the additional openings to form level 2 contacts. Level 2 bitlines are formed in electrical contact with the level 2 contacts.

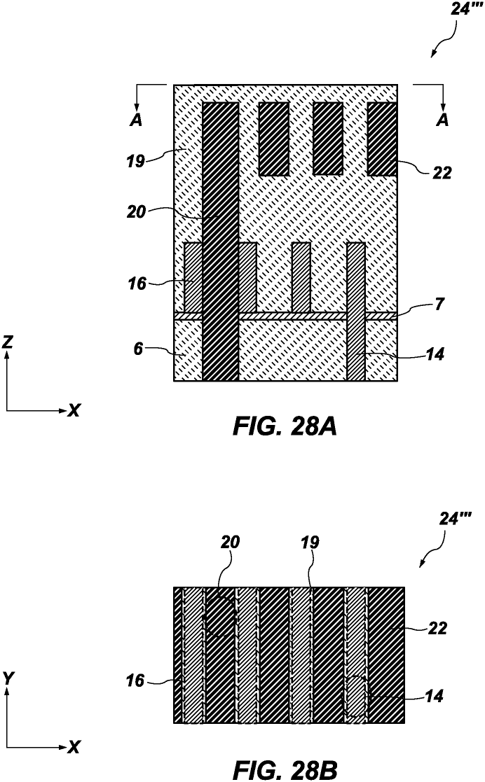

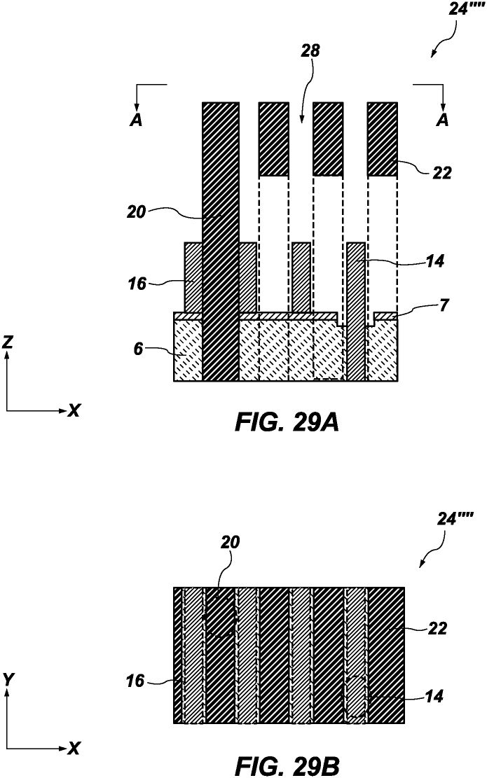

Additional electronic devices 24'" and 24'''' (see FIGS. 28A-29B) are also disclosed and are similar to the electronic devices 24, 24'. The electronic devices 24'" and 24"" include L1 contacts 14, L1 bitlines 16, L2 contacts 20, and L2 bitlines 22. The electronic device 24"" also includes air gaps 28. Methods of forming the electronic devices 24'" and 24'''' are shown in FIGS. 20A-27B and may be used to substantially reduce or prevent misalignment of the first and second levels (e.g., the first and second decks) of the electronic devices 24'" and 24'''' compared to the methods used to form the electronic devices 24, 24' described above. Features (e.g., materials and structures) and method acts of forming the electronic devices 24'" and 24'''' that are substantially similar to those of the electronic devices 24, 24' are as described above. Features and method acts that differ from those described above are further described below. While the electronic devices 24"' and 24"" are described and illustrated without a liner 26, the liner 26 may be present.

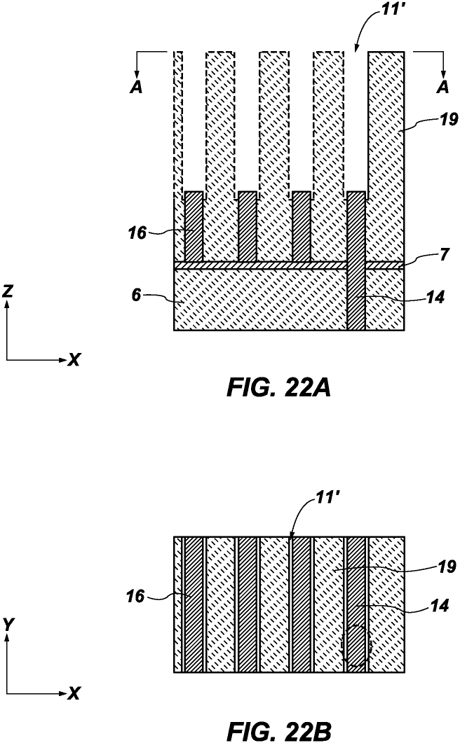

As shown in FIGS. 20A and 20B, a first dielectric material 6 and a fourth dielectric material 7 may be formed and patterned. The first dielectric material 6 and the fourth dielectric material 7 may be one of the dielectric materials previously discussed and are selected to exhibit etch selectivity. In some embodiments, the first dielectric material 6 is silicon oxide and the fourth dielectric material 7 is silicon nitride. Openings 9 are formed through the fourth dielectric material 7 to expose locations in the first dielectric material 6 where L1 contacts 14 (see FIGS. 22A and 22B) are ultimately to be formed. The openings 9 may be formed by conventional photolithography and removal techniques. In FIGS. 20A and 20B, a single material is shown as the first dielectric material 6 for convenience. However, two or more materials may be used, such as first dielectric material 6 and second dielectric material 8.

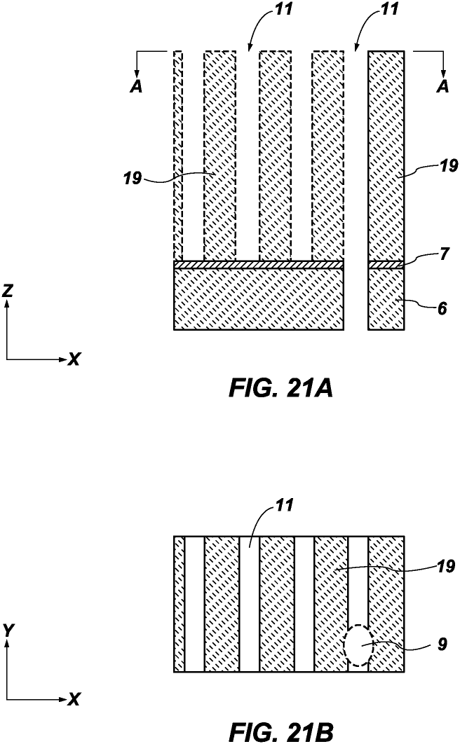

A third dielectric material 19 is formed over the first dielectric material 6 and the fourth dielectric material 7 and openings 11 are formed into and through the first dielectric material 6, as shown in FIGS. 21A and 21B. The third dielectric material 19 may be one of the dielectric materials previously discussed. In some embodiments, the third dielectric material 19 is an interlayer dielectric material. The openings 11 are formed in locations where L1 bitlines 16 (see FIGS. 22A and 22B) are ultimately to be formed. In some locations, the openings 11 are formed through the third dielectric material 19 and through the first dielectric material 6. The openings 11 may be formed by conventional photolithography and removal techniques. The openings 11 that extend into and through the first dielectric material 6 are formed in locations where the L1 contacts 14 and the L1 bitlines 16 (see FIGS. 22A and 22B) are ultimately to be formed.

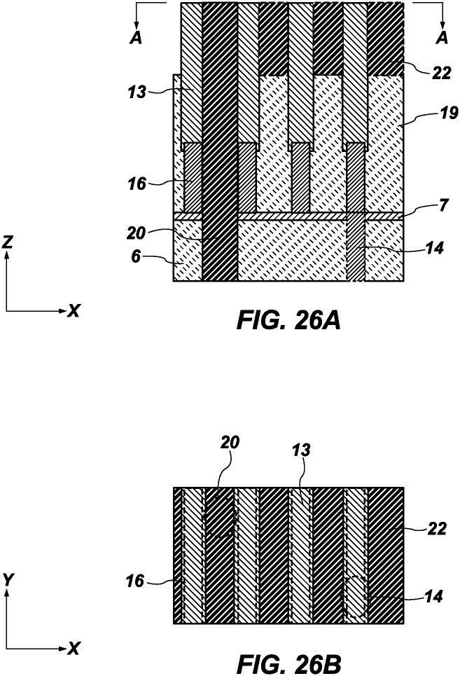

One or more conductive materials of the L1 contacts 14 and the L1 bitlines 16 are formed in the openings 11, as shown in FIGS. 22A and 22B. The conductive material may be one or more of the conductive materials previously discussed. In some embodiments, the conductive material of the L1 contacts 14 and the L1 bitlines 16 is tungsten and titanium nitride is used as a liner for the tungsten of the L1 bitlines 16. However, in other embodiments, different conductive materials may be used for the L1 contacts 14 and the L1 bitlines 16. The conductive material may formed by conventional techniques, at least partially filling the openings 11 to form the L1 contacts 14 and the L1 bitlines 16. If the openings 11 are substantially filled with the conductive material, a portion of the conductive material is removed to recess the conductive material and form the L1 contacts 14 and the L1 bitlines 16. A portion of the third dielectric material 19 may then be removed, widening the openings 11 to form openings 11' and to expose upper sidewalls of the L1 bitlines 16. A desired portion of the third dielectric material 19 may be removed by conventional techniques, such as by a wet etch process. The increased width of the openings 11' enables a width at which the L2 bitlines 22 and L2 contacts 20 (see FIGS. 26A and 26B) are formed to be larger than a width of the L1 contacts 14 and the L1 bitlines 16 and reduces or prevents shorting between the L1 contacts 14, the L1 bitlines 16, the L2 bitlines 22, and the L2 contacts 20.

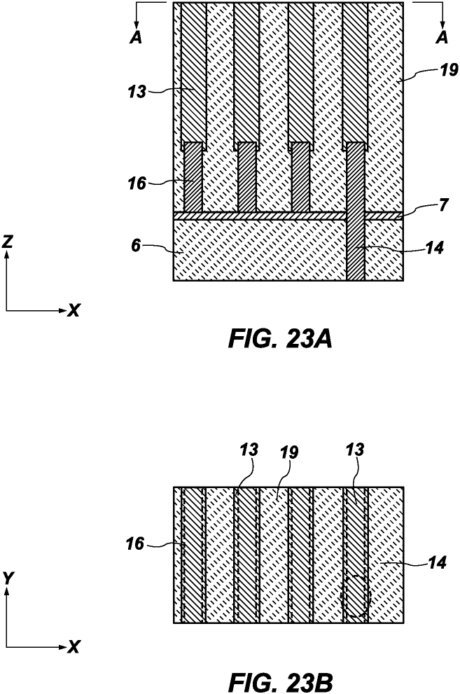

As shown in FIGS. 23A and 23B, a cap material 13 may be formed in the openings 11'. Since the openings 11' are wider than the openings 11 in which the L1 bitlines 16 are formed, the cap material 13 formed over the L1 bitlines 16 exhibits a greater width than a width of the L1 bitlines 16. The cap material 13 may be a dielectric material. In some embodiments, the cap material 13 is silicon nitride. Excess cap material 13 formed over an upper surface of the third dielectric material 19 may be removed, such as by a CMP process. An upper surface of the cap material 13 may be substantially coplanar with the upper surface of the third dielectric material 19. The cap material 13 protects the underlying L1 bitlines 16 during formation of the L2 contacts 20 and L2 bitlines 22.

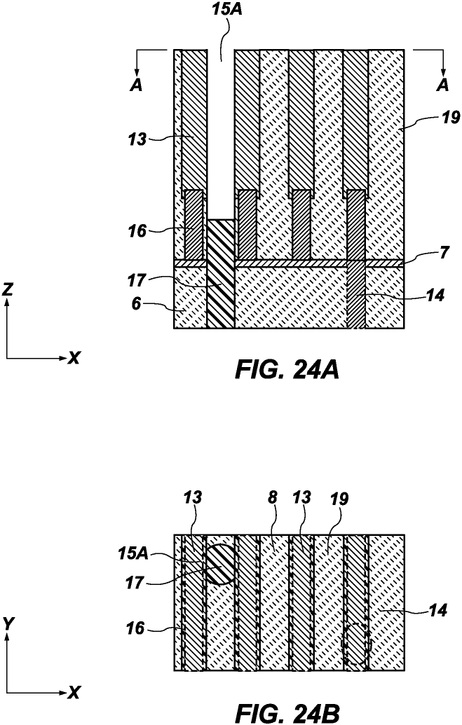

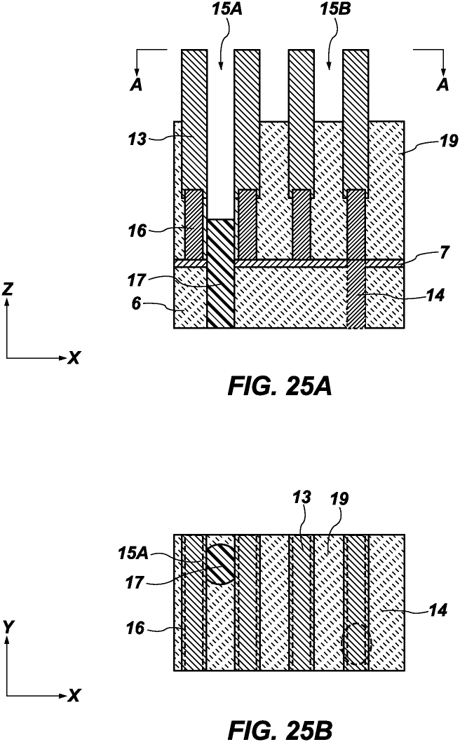

To form the L2 contacts 20 and L2 bitlines 22, openings 15 (15A, 15B) are formed in the third dielectric material 19 as shown in FIGS. 24A-25B. The openings 15 may be formed by conducting multiple photolithography and removal acts. By way of example only, the openings 15 may be formed by a dry etch process. The openings 15A are formed through the third dielectric material 19 and the first dielectric material 6 in locations where the L2 contacts 20 are ultimately to be formed, as shown in FIGS. 25A and 25B. The openings 15A may be formed by conventional techniques, such as by conducting a reactive ion etch (RIE) process. A sacrificial material 17, such as a resist material, is formed in the openings 15A to protect materials underlying the sacrificial material 17 while the openings 15B are formed. The sacrificial material 17 may at least partially fill the openings 15A. If the sacrificial material 17 substantially fills the openings 15A, a portion of the sacrificial material 17 may be removed to recess the sacrificial material 17 in the openings 15A. As shown in FIGS. 25A and 25B, the openings 15B are formed in locations where the L2 bitlines 22 are ultimately to be formed. The openings 15B may be formed by conventional techniques, such as by conventional selective reactive ion etching techniques. Conventional photolithography techniques may be used to protect other portions of the memory array.

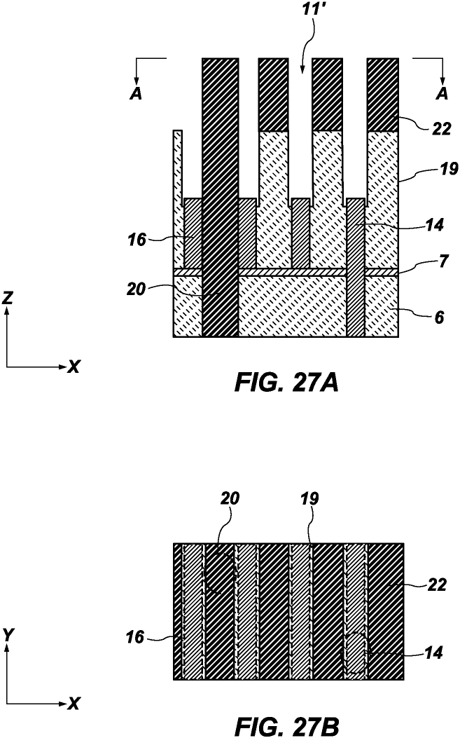

After removing the sacrificial material 17, one or more conductive materials may be formed in the openings 26A, 26B to form the L2 contacts 20 and L2 bitlines 22, as shown in FIGS. 26A and 26B. The L2 contacts 20 and L2 bitlines 22 may exhibit substantially the same width due, in part, to the widening of the openings 11'. By widening the openings 11', the width of the openings 15A, 15B may be narrowed and the L2 bitlines 22 and L2 contacts 20 formed therein may be correspondingly narrowed compared to their relative widths in the electronic devices 24, 24'. The conductive material may be one or more of the conductive materials previously discussed and may be formed by conventional techniques. In some embodiments, the conductive material of the L2 contacts 20 and the L2 bitlines 22 is tungsten and titanium nitride is used as a liner for the tungsten. However, in other embodiments, different conductive materials may be used for the L2 contacts 20 and the L2 bitlines 22. Excess conductive material may be removed from over the cap material 13, such as by CMP. The cap material 13 may then be removed, as shown in FIGS. 27A and 27B, forming the openings 11' and exposing a portion of the L1 bitlines 16. The cap material 13 may be removed by conventional techniques.

As shown in FIGS. 28A and 28B, additional third dielectric material 19 is formed in the openings 11', in place of the cap material 13, to form the electronic device 24"'. Since the openings 11' are wider than the L1 bitlines 16, the third dielectric material 19 may also be formed around a portion of the upper sidewalls of the L1 bitlines 16. The third dielectric material 19 may be formed between the L2 contacts 20 and the L2 bitlines 22 and over the L1 bitlines 16 by conventional techniques. In some embodiments, the third dielectric material 19 is silicon dioxide. Excess third dielectric material 19 may be removed, such as by CMP, forming the electronic device 24'" of FIGS. 28A and 28B. Adjacent (e.g., laterally adjacent) L2 bitlines 22 of the electronic device 24''' may, therefore, be separated from one another by the third dielectric material 19 and adjacent (e.g., laterally adjacent) L1 bitlines 16 may be separated from one another by the third dielectric material 19. In addition, adjacent (e.g., laterally adjacent) L2 contacts 20 may be separated from one another by the third dielectric material 19 and adjacent (e.g., laterally adjacent) L1 contacts 14 may be separated from one another by the third dielectric material 19 and the first dielectric material 6. The third dielectric material 19, therefore, isolates the conductive components (e.g., the L1 contacts 14, the L1 bitlines 16, the L2 contacts 20, the L2 bitlines 22) of the electronic device 24"'.

To form the electronic device 24"" shown in FIGS. 29A and 29B, exposed portions of the third dielectric material 19 in FIGS. 27A and 27B may be removed to form the air gaps 28'. The electronic device 24"" includes the air gaps 28', which are formed by removing portions of the third dielectric material 19. The third dielectric material 19 below the L2 bitlines 22 may be removed to form the air gaps 28' that extend from a lower surface of the L2 bitlines 22 and into the first dielectric material 6. The air gaps 28' are located between the L2 contacts 20, the L2 bitlines 22, and the L1 bitlines 16. The air gaps 28' may also extend below the L1 bitlines 16 proximal to the L2 contacts 20 in the first dielectric material 6. Adjacent (e.g., laterally adjacent) L2 bitlines 22 may, therefore, be separated from one another by the air gaps 28' and adjacent (e.g., laterally adjacent) L1 bitlines 16 may be separated from one another by the air gaps 28'. In addition, adjacent (e.g., laterally adjacent) L2 contacts 20 may be separated from one another by the air gaps 28' and adjacent (e.g., laterally adjacent) L1 contacts 14 may be separated from one another by the air gaps 28'. The air gaps 28', therefore, isolate the conductive components (e.g., the L1 contacts 14, the L1 bitlines 16, the L2 contacts 20, the L2 bitlines 22) of the electronic device 24"".

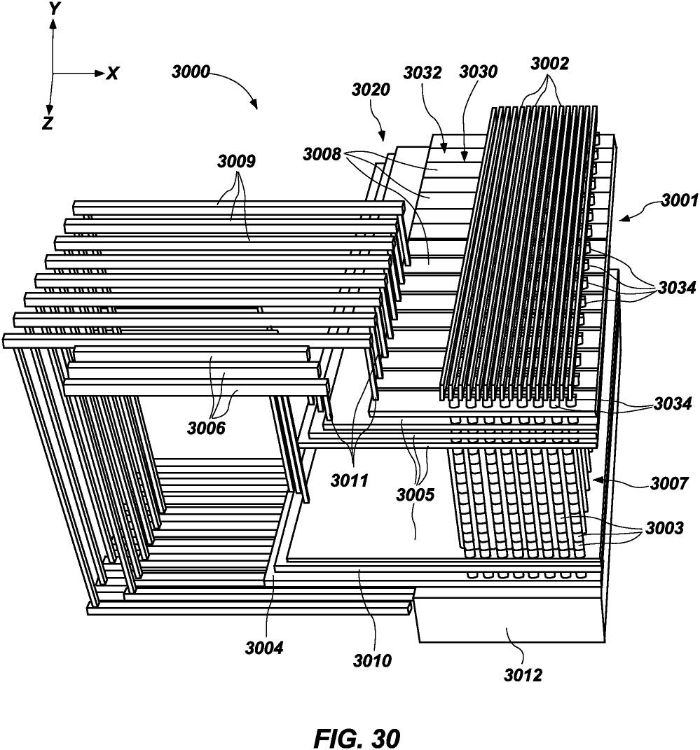

The multilevel bitlines 16, 22 according to embodiments of the disclosure correspond to multilevel bitlines 3002 and are electrically connected to access lines (e.g., wordlines 3005), as shown in apparatus 3000 of FIG. 30. The apparatus 3000 includes the multilevel bitlines 3002 (e.g., first bitlines 16 and second bitlines 22) of one or more of the electronic device 24, 24', 24"', or 24"". The multilevel bitlines 3002 are shown schematically in FIG. 30 for simplicity. However, the multilevel bitlines 3002 are as described above. The apparatus 3000 includes blocks (e.g., memory blocks), with each block including multiple subblocks 2 that contain the multilevel bitlines 3002. In some embodiments, each block includes four subblocks 2. In other embodiments, each block includes six subblocks 2. The apparatus 3000 may include a staircase structure 3020 defining contact regions for connecting the wordlines 3005 to conductive materials of tiers, which are positioned below the pillar contacts 4. The apparatus 3000 may include vertical strings 3007 of memory cells that are coupled to each other in series. The vertical strings 3007 may extend vertically (e.g., in the Z-direction) and orthogonally to the multilevel bitlines 3002. The apparatus 3000 also includes first select gates 3008 (e.g., upper select gates, select gate drains (SGDs)), select lines 3009, and a second select gate 3010 (e.g., a lower select gate, a source select gate (SGS)).

The apparatus 3000 may also include a control unit 3012 positioned under the staircase structure 3020. The control unit 3012 may include at least one of string driver circuitry, pass gates, circuitry for selecting gates, circuitry for selecting the multilevel bitlines and the wordlines 3005, circuitry for amplifying signals, and circuitry for sensing signals. The control unit 3012 may be electrically coupled to the multilevel bitlines 3002, the wordlines 3005, a source tier 3004, the first select gates 3008, and the second select gates 3010, for example. In some embodiments, the control unit 3012 includes CMOS (complementary metal-oxide-semiconductor) circuitry. In such embodiments, the control unit 3012 may be characterized as having a "CMOS under Array" ("CuA") configuration. The electronic devices 24, 24', 24"', or 24"" or apparatus 3000 according to embodiments of the disclosure may include, but is not limited to, a 3D electronic device, such as a 3D NAND Flash memory device, (e.g., a multideck 3D NAND Flash memory device).

During use and operation, the apparatus 3000 containing the first bitlines 16 and the second bitlines 22 (e.g., the multilevel bitlines 16, 22) may be independently controlled by a respective SGD 3008 of the subblock 2. The SGDs 3008 are formed adjacent to (e.g., over) the first bitlines 16 and the second bitlines 22, as known in the art. Within a particular block, the wordlines 3005 are connected together and the SGDs 3008 have different biases and may be separately controlled. Therefore, the first bitlines 16 and the second bitlines 22 may be independently switched between on and off statues using the SGDs 3008.

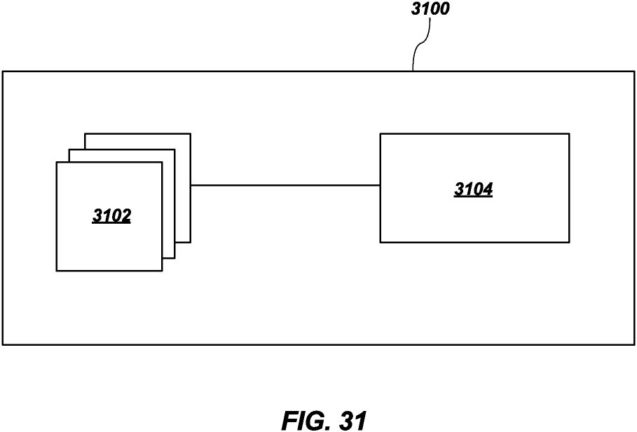

The electronic devices 24, 24', 24"', or 24"" or apparatus 3000 may be present in a memory array 3100, as shown schematically in FIG. 31. The memory array 3100 includes a memory array of memory cells 3102 and a control logic component 3104. The electronic devices 24, 24', 24"', or 24"" or the apparatus 3000 according to embodiments of the disclosure include multiple memory cells. The control logic component 3104 may be configured to operatively interact with the memory array of memory cells 3102 so as to read, write, or re-fresh any or all memory cells within the memory array of memory cells 3102. The memory cells of the memory array 3100 are coupled to access lines (e.g., the wordlines 3005), and the access lines are coupled to control gates of the memory cells. A string of memory cells of the memory array 3100 is coupled in series between a source line and the multilevel bitlines 3002. The memory cells are positioned between the wordlines 3005 and the multilevel bitlines 3002. The wordlines 2005 may be in electrical contact with, for example, conductive materials of the tiers, and the multilevel bitlines 3002 may be in electrical contact with an electrode (e.g., a top electrode) of the tiers. The multilevel bitlines 3002 may directly overlie a row or column of the memory cells and contact the top electrode thereof. Each of the wordlines 3005 may extend in a first direction and may connect a row of the memory cells. Each of the multilevel bitlines 3002 may extend in a second direction that is at least substantially perpendicular to the first direction and may connect a column of the memory cells. A voltage applied to the wordlines 3005 and the multilevel bitlines 3002 may be controlled such that an electric field may be selectively applied at an intersection of at least one wordline 3005 and at least one multilevel bitline 3002, enabling the memory cells to be selectively operated. Additional process acts to form the memory array 3100 including the electronic devices 24, 24', 24"', or 24"" or apparatus 3000 are conducted by conventional techniques.

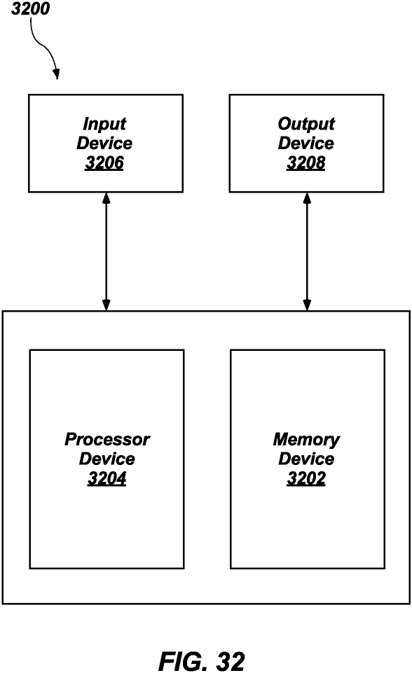

An electronic system 3200 is also disclosed, as shown in FIG. 32, and includes the electronic devices 24, 24', 24"', or 24"" or apparatus 3000 according to embodiments of the disclosure. FIG. 32 is a simplified block diagram of the electronic system 3200 implemented according to one or more embodiments described herein. The electronic system 3200 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPad® or SURFACE® tablet, an electronic book, a navigation device, etc. The electronic system 3200 includes at least one memory device 3202, which includes the electronic devices 24, 24', 24"', or 24"" or apparatus 3000 as previously described. The electronic system 3200 may further include at least one processor device 3204, such as a microprocessor, to control the processing of system functions and requests in the electronic system 3200. The processor device 3204 and other subcomponents of the electronic system 3200 may include the memory cells. The processor device 3204 may, optionally, include one or more memory arrays 3100 as previously described.

Various other devices may be coupled to the processor device 3204 depending on the functions that the electronic system 3200 performs. For example, an input device 3206 may be coupled to the processor device 3204 for inputting information into the electronic system 3200 by a user, such as, for example, a mouse or other pointing device, a button, a switch, a keyboard, a touchpad, a light pen, a digitizer and stylus, a touch screen, a voice recognition system, a microphone, a control panel, or a combination thereof. An output device 3208 for outputting information (e.g., visual or audio output) to a user may also be coupled to the processor device 3204. The output device 3208 may include an LCD display, an SED display, a CRT display, a DLP display, a plasma display, an OLED display, an LED display, a three-dimensional projection, an audio display, or a combination thereof. The output device 3208 may also include a printer, an audio output jack, a speaker, etc. In some embodiments, the input device 2206 and the output device 3208 may comprise a single touchscreen device that can be used both to input information to the electronic system 3200 and to output visual information to a user. The one or more input devices 3206 and output devices 3208 may communicate electrically with at least one of the memory device 3202 and the processor device 3204. The at least one memory device 3202 and processor device 3204 may also be used in a system on chip (SoC).

Accordingly, a system is disclosed. The system comprises a processor operably coupled to an input device and an output device, and an electronic device operably coupled to the processor. The electronic device comprises multilevel bitlines comprising first bitlines and second bitlines. The first bitlines and second bitlines are positioned at different levels and the first bitlines and the second bitlines are electrically connected to wordlines. Level 1 contacts are electrically connected to the first bitlines and level 2 contacts are electrically connected to the second bitlines. Pillar contacts are electrically connected to the level 1 contacts and to the level 2 contacts.

While certain illustrative embodiments have been described in connection with the figures, those of ordinary skill in the art will recognize and appreciate that embodiments encompassed by the disclosure are not limited to those embodiments explicitly shown and described herein. Rather, many additions, deletions, and modifications to the embodiments described herein may be made without departing from the scope of embodiments encompassed by the disclosure, such as those hereinafter claimed, including legal equivalents. In addition, features from one disclosed embodiment may be combined with features of another disclosed embodiment while still being encompassed within the scope of the disclosure.

What is claimed is:

1. An electronic device comprising:
multilevel bitlines comprising first bitlines and second bitlines, the first bitlines and the second bitlines positioned at different levels;
pillar contacts electrically connected to the first bitlines and to the second bitlines;
level 1 contacts electrically connected to the first bitlines; and
level 2 contacts electrically connected to the second bitlines,
each bitline of the first bitlines electrically connected to a single pillar contact adjacent to the level 1 contacts and each bitline of the second bitlines electrically connected to a single pillar contact adjacent to the level 2 contacts.

2. The electronic device of claim 1, wherein the bitlines of the first bitlines are equally spaced from one another.

3. The electronic device of claim 1, wherein the bitlines of the second bitlines are equally spaced from one another.

4. The electronic device of claim 1, wherein the first bitlines and the second bitlines are equally spaced from one another.

5. The electronic device of claim 1, wherein a conductive material of the first bitlines, the second bitlines, the level 1 contacts, and the level 2 contacts is the same material.

6. The electronic device of claim 1, wherein a conductive material of one or more of the first bitlines, the second bitlines, the level 1 contacts, or the level 2 contacts is the same conductive material.

7. The electronic device of claim 1, wherein the pillar contacts exhibit a staggered configuration.

8. The electronic device of claim 1, wherein the first bitlines are electrically connected to a single level 1 contact.

9. The electronic device of claim 1, wherein the second bitlines are electrically connected to a single level 2 contact.

10. The electronic device of claim 1, wherein the second bitlines and the level 2 contacts exhibit substantially the same width.

11. The electronic device of claim 1, wherein laterally adjacent first bitlines are separated from one another by air gaps.

12. The electronic device of claim 1, wherein laterally adjacent second bitlines are separated from one another by air gaps.

13. An electronic device comprising:
multilevel bitlines comprising first bitlines and second bitlines, the first bitlines and the second bitlines parallel to one another and equally spaced from one another;
level 1 contacts adjacent to the first bitlines, each of the first bitlines electrically connected to a single level 1 contact;
level 2 contacts adjacent to the second bitlines, each of the second bitlines electrically connected to a single level 2 contact; and
each bitline of the first bitlines electrically connected to a single pillar contact adjacent to the level 1 contacts and each bitline of the second bitlines electrically connected to a single pillar contact adjacent to the level 2 contacts.

14. The electronic device of claim 13, wherein the first bitlines and the second bitlines extend at different heights within the electronic device.

15. The electronic device of claim 13, wherein a conductive material of the first bitlines and the second bitlines is the same conductive material.

16. The electronic device of claim 13, wherein a conductive material of the first bitlines and the second bitlines is different.

17. The electronic device of claim 13, wherein a length of the level 1 contacts is less than a length of the level 2 contacts.

18. The electronic device of claim 13, wherein a width of the first bitlines is substantially the same as a width of the level 1 contacts.

19. The electronic device of claim 13, wherein a width of the second bitlines is substantially the same as a width of the level 2 contacts.

20. A system, comprising:
a processor operably coupled to an input device and an output device; and
an electronic device operably coupled to the processor, the electronic device comprising:
multilevel bitlines comprising first bitlines and second bitlines, the first bitlines and the second bitlines positioned at different levels and the first bitlines and the second bitlines electrically connected to wordlines;
level 1 contacts electrically connected to the first bitlines;
level 2 contacts electrically connected to the second bitlines; and
pillar contacts electrically connected to the level 1 contacts and to the level 2 contacts.

21. The system of claim 20, wherein each of the first bitlines is electrically connected to a pillar contact and each of the second bitlines is electrically connected to a separate pillar contact.

22. The system of claim 20, wherein each pillar contact of the pillar contacts is electrically connected to a single first bitline or to a single second bitline.

23. The system of claim 20, wherein one or more of the first bitlines is laterally offset from another first bitline.

24. A method of forming an electronic device, comprising:
forming pillar contacts in a first dielectric material;
forming a second dielectric material adjacent to the pillar contacts;
forming openings through the second dielectric material to expose the pillar contacts;
forming a conductive material in the openings to form level 1 contacts;
forming level 1 bitlines in electrical contact with the level 1 contacts;
forming a low-k dielectric material over the level 1 bitlines;
forming additional openings through the low-k dielectric material and the second dielectric material to expose additional pillar contacts;
forming a conductive material in the additional openings to form level 2 contacts; and
forming level 2 bitlines in electrical contact with the level 2 contacts.

25. The method of claim 24, wherein forming pillar contacts in a first dielectric material comprises forming the pillar contacts in a staggered configuration.

26. The method of claim 24, wherein forming openings through the second dielectric material to expose the pillar contacts comprises forming the openings to expose only a portion of the pillar contacts.

27. The method of claim 24, wherein forming level 1 bitlines in electrical contact with the level 1 contacts comprises forming each of the level 1 bitlines in electrical contact with a single level 1 contact.

28. The method of claim 24, wherein forming level 1 bitlines in electrical contact with the level 1 contacts and forming level 2 bitlines in electrical contact with the level 2 contacts comprises forming the level 1 bitlines and the level 2 bitlines equally spaced from one another.

29. The method of claim 24, wherein forming additional openings through the low-k dielectric material and the second dielectric material to expose additional pillar contacts comprises forming the additional openings to expose a remaining portion of the pillar contacts.

30. The method of claim 24, further comprising removing one or more dielectric materials between the level 2 bitlines to form air gaps between adjacent level 2 bitlines.
